(19) United States
(12) Patent Application Publication
(10) Pub. No.: US 2011/0147198 A1
(43) Pub. Date: Jun. 23, 2011

(54) VACUUM PUMPING SYSTEM, OPERATING METHOD OF VACUUM PUMPING SYSTEM, REFRIGERATOR, VACUUM PUMP, OPERATING METHOD OF REFRIGERATOR, OPERATION CONTROL METHOD OF TWO-STAGE TYPE REFRIGERATOR, OPERATION CONTROL METHOD OF CRYOPUMP, TWO-STAGE TYPE REFRIGERATOR, CRYOPUMP, SUBSTRATE PROCESSING APPARATUS, AND MANUFACTURING METHOD OF ELECTRONIC DEVICE

(75) Inventors: Takahiro Okada, Minamitsuru-gun (JP); Kazutoshi Aoki, Minamitsuru-gun (JP); Hisayoshi Komai, Minamitsuru-gun (JP)

(73) Assignee: CANON ANELVA CORPORATION, Kawasaki-shi (JP)

(21) Appl. No.: 13/037,819

(22) Filed: Mar. 1, 2011

Related U.S. Application Data
(63) Continuation of application No. PCT/JP2009/004967, filed on Sep. 29, 2009.

(30) Foreign Application Priority Data
Sep. 30, 2008 (JP) 2008-253916
Sep. 30, 2008 (JP) 2008-253919

(51) Int. Cl. B01D 8/00; C23C 14/34

(52) U.S. Cl. 204/192.1; 62/55.5; 204/298.02

(57) ABSTRACT

A plurality of vacuum pumps each having a refrigerator are connected to a common compressor. At least one of the plurality of vacuum pumps performs an operation for repeating an operation including a process in which a gas in a low-pressure state is adiabatically compressed when the interior of a cylinder shifts from the low-pressure state to a high-pressure state as a result of a valve operation of the refrigerator, and a process in which a displacer passes through the adiabatically compressed gas. At least another one of the plurality of vacuum pumps performs an operation for repeating an operation including a process in which a gas in the high-pressure state is adiabatically expanded when the interior of the cylinder shifts from the high-pressure state to the low-pressure state as a result of the valve operation of the refrigerator, and a process in which the displacer passes through the adiabatically expanded gas.

### TECHNICAL FIELD

The present invention relates to a vacuum pumping system, an operating method of a vacuum pumping system, a refrigerator, a vacuum pump, an operating method of a refrigerator, an operation control method of a two-stage type refrigerator, an operation control method of a cryopump, a two-stage type refrigerator, a cryopump, a substrate processing apparatus, and a manufacturing method of an electronic device.

### BACKGROUND ART

Since vacuum pumps used in the manufacturing processes of semiconductors, electronic components, and the like are required to be oil-free and to obtain an ultra-high vacuum state, vacuum pumps using low temperatures are popularly used.

As such vacuum pumps using low temperatures, a cryopump which can attain an ultra-high vacuum and has two cooling stages, a cryotrap having a single cooling stage, and the like are available.

Most of these vacuum pumps that use low temperatures condense or adsorb a gas using a low temperature obtained upon adiabatic expansion of a high-pressure gas generated by a compressor. In recent years, vacuum pumping systems using low temperatures are prevalently used, due to the aforementioned satisfactory characteristics. Recently, a multi-operation vacuum pumping system, which is advantageous in a cost reduction and energy savings and operates a plurality of vacuum pumps using a common compressor, is used (patent literature 1, etc.)

Patent literature 1 describes a vacuum pumping system in which a plurality of cryopumps are operated by a single compressor. Patent literature 1 discloses that a gas distributor, which branches a helium gas from the compressor and adjusts helium supply pressures for respective branches, is interposed between the compressor and the plurality of cryopumps, and the compressor can supply the helium gas at a supply pressure equal to or larger than a maximum value that each of the plurality of cryopumps requires.

Patent literature 2 discloses a cryopump in which the number of times of repetition of high- and low-pressure states in a refrigerator per unit time is feedback-controlled based on the temperature of a first cooling stage, and the temperature of the first cooling stage can be maintained within a given range.

Furthermore, patent literature 2 discloses an invention in which when a plurality of cryopumps are operated by a single compressor, a constant pressure difference between gases in high- and low-pressure pipes is maintained by controlling the cycle time of the compressor.

### CITATION LIST

### Patent Literature

PTL1: Japanese Patent Laid-Open No. 4-209979 (FIG. 1, etc.)
PTL2: Japanese Patent Laid-Open No. 2004-3792 (FIG. 1, FIG. 2, etc.)

### SUMMARY OF INVENTION

### Technical Problem

However, when the plurality of cryopumps are operated by the single compressor, as described in patent literature 1, the compressor generates, in advance, a helium gas of a pressure equal to or larger than a maximum value of a pressure that one of the plurality of vacuum pumps requires. A high-pressure helium gas is generated by the compressor. However, as for a vacuum pump having a low-temperature stage, most of its consumption energy is used to generate a high-pressure helium gas. Therefore, in order to reduce the consumption energy of the whole vacuum pumping system, the pressure and generation amount of the high-pressure helium gas to be generated have to be reduced.

However, in the invention described in patent literature 1, since a helium gas pressure excessively higher than necessary has to be generated in advance, a problem is posed in terms of energy consumption.

The energy consumption problem will be described in detail below using FIG. 10. FIG. 10 is a graph showing the relationship between the pressure difference between helium gases in high- and low-pressure pipes, which connect a compressor and respective cryopumps, and the consumption power when one compressor operates four cryopumps. Note that a thermal load is kept constant throughout experiments.

When the thermal load is constant, a refrigerating performance is proportional to the product of an operating frequency of a refrigerator and the pressure difference between gases in the high- and low-pressure pipes. Note that the operating frequency of the refrigerator means the number of times of repetition of high- and low-pressure states per unit time in the refrigerator. Therefore, in case of FIG. 10, the operating frequency itself of the refrigerator decreases with increasing pressure difference between gases in the high- and low-pressure pipes, in consideration of the refrigerating performance.

When the operating frequency of the refrigerator increases, the consumption energy of the refrigerator itself may increase. However, since the consumption energy of the refrigerator is at most 100 W, those of four refrigerators amount to at most 400 W. On the other hand, when the pressure difference between gases in the high- and low-pressure pipes is increased from 1.2 MPa to 1.6 MPa in FIG. 10, the consumption energy increases from about 3500 W to about 4900 W.

Therefore, assume that the cryopumps pumping a gas having an identical thermal load while the pressure difference between gases in the high- and low-pressure pipes is set to be 1.2 MPa and 1.6 MPa. Then, pumping at the pressure difference=1.2 MPa can save a consumption energy by 1000 W or more compared to that at the pressure difference=1.6 MPa.

On the other hand, in a regeneration operation, it is required to increase a heat value at the time of temperature rising. This is to reduce a downtime of an apparatus which performs processes using a vacuum. The refrigerator can have a heating function by changing its way of operation. The regeneration operation means an operation which raises the temperature of a cooling portion such as a stage by a heating operation of the refrigerator having the heating function to evaporate a condensed or adsorbed material and to remove them from the cooling portion such as the stage.

However, the arrangement and operating method of a vacuum pump system which quickly switches a vacuum pump in a regeneration operation state to a vacuum pumping operation state while maintaining the vacuum pumping operations of vacuum pumps other than that which performs the activation operation have never been proposed.

The invention described in patent literature 2 discloses an invention which maintains the temperatures of first cooling stages of a plurality of cryopumps within a given range. In this case, a constant pressure difference between gases in the high- and low-pressure pipes is maintained. However, only maintaining a constant pressure difference between gases in the high- and low-pressure pipes poses a problem in terms of a reduction of the regeneration operation time while maintaining the vacuum pumping operations of vacuum pumps other than that which performs the activation operation.

### Solution to Problem

In consideration of the aforementioned problems, the present invention has as its object to provide a vacuum pumping technology which reduces energy consumption in a vacuum pumping system in which a plurality of vacuum pumps each having a cooling stage are connected to a compressor and are operated by the compressor.

Or the present invention has as its object to provide a vacuum pumping technology which can control vacuum pumps that perform an cool-down operation or regeneration operation to quickly return to a state of a vacuum pumping operation.

A vacuum pumping system according to one aspect of the present invention is characterized by comprising:

a plurality of vacuum pumps each of which comprises a refrigerator, which includes a first cooling stage and cools the first cooling stage, and a first temperature sensor which measures a temperature of the first cooling stage, increases the number of times of repetition of a high-pressure stage and a low-pressure stage per unit time in the refrigerator when the temperature measured by the first temperature sensor is higher than a predetermined temperature range, decreases the number of times when the temperature measured by the first temperature sensor is lower than the predetermined temperature range, and maintains the number of times when the temperature measured by the first temperature sensor falls within the predetermined temperature range;

a compressor connected to the plurality of vacuum pumps;

a high-pressure pipe which serves as a flow path through which a high-pressure gas of a common pressure is supplied from the compressor to the refrigerators of the plurality of vacuum pumps;

a low-pressure pipe which serves as a flow path through which a low-pressure gas flows back from the refrigerators of the plurality of vacuum pumps to the compressor; and

control means capable of changing a pressure difference between an internal pressure of the high-pressure pipe and an internal pressure of the low-pressure pipe according to the number of times.

An operating method of a vacuum pumping system according to another aspect of the present invention is an operating method of a vacuum pumping system comprising

a plurality of vacuum pumps each comprising a refrigerator, which includes a first cooling stage and cools the first cooling stage, and a first temperature sensor which measures a temperature of the first cooling stage,

a compressor connected to the plurality of vacuum pumps,

a high-pressure pipe which serves as a flow path through which a high-pressure gas of a common pressure is supplied from the compressor to the refrigerators of the plurality of vacuum pumps, and

a low-pressure pipe which serves as a flow path through which a low-pressure gas flows back from the refrigerators of the plurality of vacuum pumps to the compressor,

the operating method comprising:

a step of controlling each of the plurality of vacuum pumps to increase the number of times of repetition of a high-pressure stage and a low-pressure stage per unit time in the refrigerator when the temperature measured by the first temperature sensor in is higher than a predetermined temperature range, to decrease the number of times when the temperature measured by the first temperature sensor is lower than the predetermined temperature range, and to maintain the number of times when the temperature measured by the first temperature sensor falls within the predetermined temperature range; and

a step of decreasing a pressure difference between gases in the high-pressure pipe and the low-pressure pipe generated by the compressor so that the number of times in the refrigerator falls within a predetermined range.

A refrigerator according to still another aspect of the present invention is a refrigerator which comprises

a cooling stage,

a cylinder which is connected to one face of the cooling stage,

a plate member which is connected to the other end face in an axial direction of the cylinder on a side opposite to the one end face of the cylinder connected to the cooling stage,

a space which is formed to be surrounded by the cooling stage, the cylinder, and the plate member,

a flow path which is formed in the plate member,

a valve which sets an interior of the cylinder in one of a high-pressure state and a low-pressure state via the flow path, and

a piston-like displacer which partitions an interior of the space into one space and the other space communicating with the flow path,

the displacer reciprocating in an axial direction in the cylinder, and the cylinder having a hollow interior including a material which preserves a heat state,

the refrigerator characterized in that when the refrigerator performs an operation for repeating an operation including

a process in which a gas in the low-pressure state is adiabatically compressed when the interior of the cylinder shifts from the low-pressure state to the high-pressure state as a result of an operation of the valve, and

a process in which the displacer passes through the adiabatically compressed gas,

the refrigerator operates to set the number of times of repetition of the high-pressure state and the low-pressure state per unit time in the refrigerator to be a higher value than a low-temperature normal operation, and to increase a pressure difference between the high-pressure state and the low-pressure state.

A refrigerator according to still another aspect of the present invention is a refrigerator which includes a cooling stage and cools the cooling state by adiabatic expansion of a high-pressure gas, characterized in that

when a vacuum pumping operation state is reached from an ambient temperature state,

the refrigerator operates to set the number of times of repetition of the high-pressure state and the low-pressure state per unit time in the refrigerator to be a higher value than a low-temperature normal operation, and to increase a pressure difference between the high-pressure state and the low-pressure state.

A refrigerator according to still another aspect of the present invention is characterized in that the refrigerator includes a cooling stage, and in a regeneration operation for evaporating a condensed or adsorbed material by rising a temperature of the cooling stage, the refrigerator operates to set the number of times of repetition of the high-pressure state and the low-pressure state per unit time in the refrigerator to be a higher value than a low-temperature normal operation, and to increase a pressure difference between the high-pressure state and the low-pressure state.

An operating method of a refrigerator according to still another aspect of the present invention is an operating method of a refrigerator, which comprises

a cooling stage,

a cylinder which is connected to one face of the cooling stage,

a plate member which is connected to the other end face in an axial direction of the cylinder on a side opposite to the one end face of the cylinder connected to the cooling stage,

a space which is formed to be surrounded by the cooling stage, the cylinder, and the plate member,

a flow path which is formed in the plate member,

a valve which sets an interior of the cylinder in one of a high-pressure state and a low-pressure state via the flow path, and

a piston-like displacer which partitions an interior of the space into one space and the other space communicating with the flow path,

the displacer reciprocating in an axial direction in the cylinder, and the cylinder having a hollow interior including a material which preserves a heat state,

the operating method characterized by controlling, when the refrigerator performs an operation for repeating an operation including

a process in which a gas in the low-pressure state is adiabatically compressed when the interior of the cylinder shifts from the low-pressure state to the high-pressure state as a result of an operation of the valve, and

a process in which the displacer passes through the adiabatically compressed gas,

the refrigerator to operate to set the number of times of repetition of the high-pressure state and the low-pressure state per unit time in the refrigerator to be a higher value than a low-temperature normal operation, and to increase a pressure difference between the high-pressure state and the low-pressure state.

An operating method of a refrigerator according to still another aspect of the present invention is an operating method of a refrigerator, which includes a cooling stage and cools the cooling stage by adiabatic expansion of a high-pressure gas, the operating method characterized by controlling,

when a vacuum pumping operation state is reached from an ambient temperature state,

the refrigerator to operate to set the number of times of repetition of the high-pressure state and the low-pressure state per unit time in the refrigerator to be a higher value than a low-temperature normal operation, and to increase a pressure difference between the high-pressure state and the low-pressure state.

An operation control method of a dual-stage type refrigerator according to still another aspect of the present invention is an operation control method of a dual-stage type refrigerator comprising a first cooling stage and a second cooling stage, a first temperature sensor which measures a temperature of the first cooling stage, a second temperature sensor which measures a temperature of the second cooling stage, and heating means for heating the first cooling stage, the operation control method characterized by comprising:

a first control step of feedback-controlling an operating frequency of the dual-stage type refrigerator based on an output from the first temperature sensor so as to maintain the temperature of the first cooling stage to be constant; and

a second control step of detecting the temperature of the second cooling stage based on an output from the second temperature sensor, and controlling a refrigerating performance of the second cooling stage by changing the operating frequency of the dual-stage type refrigerator by controlling an output from the heating means based on the detected temperature of the second cooling stage.

A dual-stage type refrigerator according to still another aspect of the present invention is characterized by comprising:

a first cooling stage;

a second cooling stage;

a first temperature sensor which measures a temperature of the first cooling stage;

a second temperature sensor which measures a temperature of the second cooling stage;

heating means for heating the first cooling stage; and

a heating controlling device which controls an output from the heating means in accordance with the temperature of the second cooling stage detected by the second temperature sensor.

A dual-stage type refrigerator according to still another aspect of the present invention is characterized by comprising:

a first cooling stage which reaches a cooling temperature within a first operating temperature width;

a second cooling stage which reaches a cooling temperature within a second operating temperature width set to have an operating temperature width lower than the first operating temperature width;

heating means for heating the first cooling stage;

control means for controlling a driving frequency of the dual-stage type refrigerator;

a first temperature sensor which measures a temperature of the first cooling stage; and

a second temperature sensor which measures a temperature of the second cooling stage,

wherein when an output value of the second temperature sensor is an output value indicating a temperature higher than a predetermined value, the control means increases the driving frequency by increasing a heating heat amount of the heating means, and when the output value of the second temperature sensor is an output value indicating a temperature lower than the predetermined value, the control means decreases the driving frequency by decreasing the heating heat amount of the heating means.

### Advantageous Effects of Invention

According to the present invention, the vacuum pumping technology which reduces energy consumption in the vacuum pumping system in which the plurality of vacuum pumps each having the cooling stage are connected to the compressor and are operated by the compressor can be provided.

Alternatively, according to the present invention, the refrigerators which perform the activation operation and regeneration operation can be controlled to be quickly returned to the state of the vacuum pumping operation.

Alternatively, according to the present invention, by raising a heating heat amount by operating the heating means, the drive power source frequency of the refrigerator is raised, thereby enhancing the refrigerating performance of the second cooling stage. Conversely, by reducing the heating heat amount of the heating means, the drive power source frequency of the refrigerator is reduced, thus lowering the refrigerating performance of the second cooling stage. Therefore, according to the present invention, the refrigerating performance of the second cooling stage can be adjusted.

Alternatively, according to the present invention, when the detected temperature of the second cooling stage is higher than the maximum value of the target temperature range, the heating means is activated to raise the heating heat amount. Then, feedback control is applied to maintain the temperature of the first cooling stage, and the drive power source frequency of the refrigerator is raised, thus enhancing the refrigerating performance of the second cooling stage accordingly. Therefore, the temperature of the second cooling stage can be reduced to fall within the target temperature range without largely varying the temperature of the first cooling stage.

Alternatively, according to the present invention, when the detected temperature of the second cooling stage is lower than the minimum value of the target temperature range, the heating heat amount of the heating means is reduced. Then, feedback control is applied to maintain the temperature of the first cooling stage, and the drive power source frequency of the refrigerator is reduced, thus lowering the refrigerating performance of the second cooling stage accordingly. Therefore, the temperature of the second cooling stage can be raised to fall within the target temperature range without largely varying the temperature of the first cooling stage, and the helium gas consumption amount can be reduced.

Other features and advantages of the present invention will become apparent from the following description taken in conjunction with the accompanying drawings. Note that the same reference numerals denote the same or similar components throughout the accompanying drawings.

### BRIEF DESCRIPTION OF DRAWINGS

The accompanying drawings, which are incorporated in and constitute a part of the specification, illustrate embodiments of the invention and, together with the description, serve to explain the principles of the invention.

FIG. 1 is a diagram showing an example of a vacuum pump used in a vacuum pumping system according to an embodiment of the present invention;

FIG. 2 is a flowchart showing the temperature adjustment sequence of a second cooling stage;

FIG. 3 is a diagram of a vacuum pumping system in which a plurality of cryotraps are operated by a single compressor;

FIG. 4 is a view showing the arrangement of a cryotrap;

FIG. 5 is a flowchart showing the operation sequence associated with a vacuum pumping system according to the first embodiment;

FIG. 6 is a graph for explaining a method of changing a pressure difference associated with the interiors of high- and low-pressure pipes;

FIG. 7 is a flowchart showing the operation sequence at the time of an activation operation or regeneration operation;

FIG. 8 is a diagram of a vacuum pumping system in which a plurality of cryopumps are operated by a single compressor;

FIG. 9 is a diagram of a vacuum pumping system in which a vacuum pumping system including both cryopumps and cryotraps is operated by a single compressor;

FIG. 10 is a graph showing the relationship between the pressure difference and consumption energy of a compressor when four cryopumps are operated to have an identical thermal load;

FIG. 11 is a sectional view showing the arrangement of a cryopump;

FIG. 12 is a diagram showing an example of the arrangement of a substrate processing apparatus using a vacuum pumping system according to the present invention; and

FIG. 13 is a sectional view exemplifying an electronic device manufactured using the substrate processing apparatus according to the present invention.

### DESCRIPTION OF EMBODIMENTS

Embodiments of the present invention will be described in detail hereinafter with reference to the drawings. A vacuum pump which is used in a vacuum pumping system of this embodiment and has a cooling stage will be described first. The principle of a cryopump as an example of the vacuum pump will be explained.

A vacuum pumping system using a cryopump includes the cryopump including a refrigerator that generates a very low temperature, and a compressor that supplies a compressed gas such as helium to the refrigerator. This system repeats a cycle for supplying a high-pressure gas from the compressor to the refrigerator, cooling the high-pressure gas in advance by a refrigerant in the refrigerator, filling up an expansion chamber with the high-pressure gas, then expanding the high-pressure gas to generate a low temperature, cooling a surrounding area and also the regenerator, and returning the gas which has a low pressure to the compressor. By condensing or adsorbing a gas by a very low temperature obtained by this refrigerating cycle, vacuum pumping is attained.

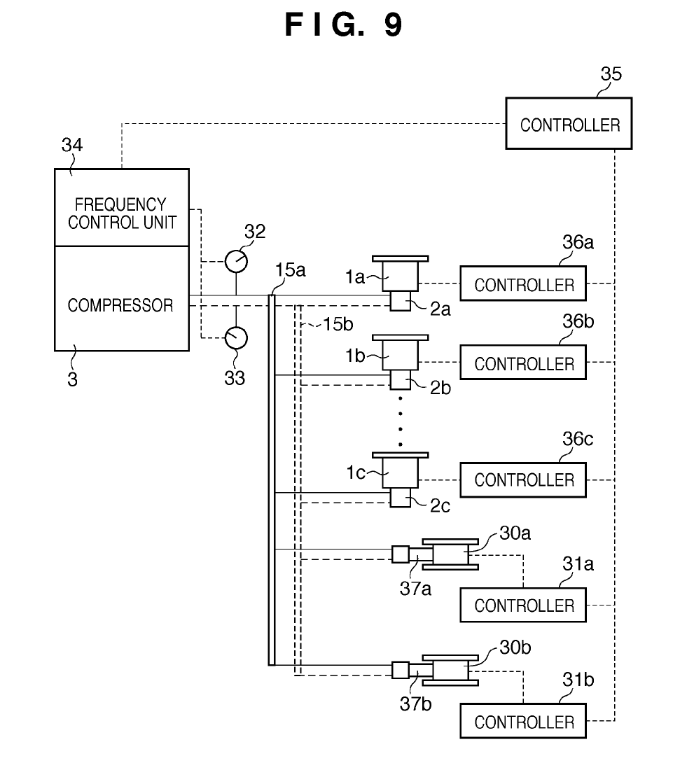

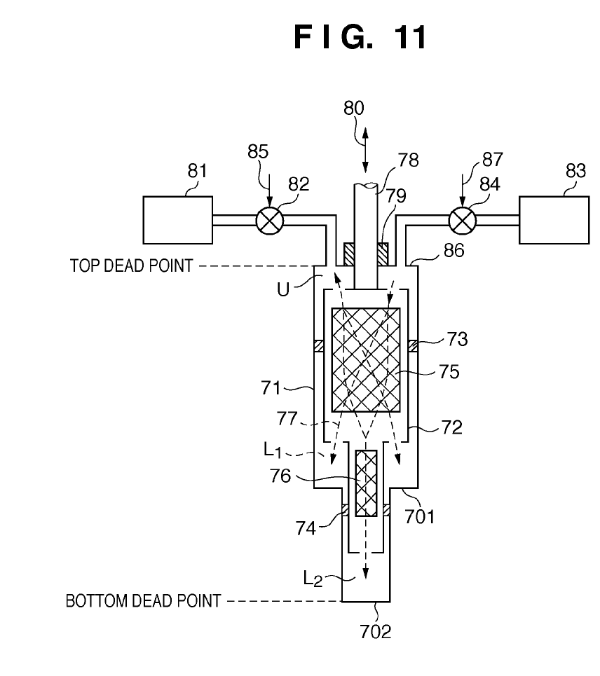

The arrangement of the refrigerator is shown in, for example, FIG. 9 of Japanese Patent Laid-Open No. 7-35070. FIG. 11 shows the arrangement of the refrigerator disclosed in FIG. 9 of that reference. FIG. 11 shows the internal structure of a cylinder of the refrigerator arranged in a pump container, a high-pressure side valve, and a low-pressure side valve. A displacer 72, which reciprocates in a slidable state, is arranged in a cylindrical cylinder 71. Ring-shaped seal members 73 and 74 are arranged between the displacer 72 and cylinder 71. As for the shape of the cylinder 71 and displacer 72, a lower portion in FIG. 11 has a smaller diameter to define a two-stage structure. A cooling stage 701 is connected to one end face having a larger diameter of the cylinder 71. A cooling stage 702 is connected to the end face having a smaller diameter of the cylinder 71. A plate member 86 is connected to the other end face in the axial direction, having the larger diameter, of the cylinder 71. The displacer 72 includes, for example, two regenerators 75 and 76. Since the regenerators 75 and 76 basically have a structure for passing a gas through them, and their structure is given, a detailed description thereof will not be given. A gas flows according to the moving state of the displacer 72, as indicated by, for example, broken lines 77. In the gas flows indicated by the broken lines 77, all directions in which the flows are likely to be generated are indicated by arrows. In practice, the flow in one of a direction from the top to the bottom and that from the bottom to the top in FIG. 11 is generated according to an operating condition. In the reciprocal motions of the displacer 72, a position when the displacer 72 reaches the top end of the cylinder 71 in FIG. 11 corresponds to the position of a top dead point, and that when it reaches the bottom end corresponds to the position of a bottom dead point.

A connecting rod 78 is joined to the top surface portion of the displacer 72, extends outside the cylinder 71, and is coupled to a rotational driving shaft of a motor (not shown) via a crank mechanism (not shown). A seal member 79 is arranged between the connecting rod 78 and cylinder 71. When the motor rotates in a certain direction, the connecting rod 78 makes reciprocal motions 80 according to the rotation of the motor through the operation of the crank mechanism. Therefore, the displacer 72 joined to the connecting rod 78 also makes reciprocal motions in the cylinder 71 in cooperation with the connecting rod 78. By the reciprocal motions of the displacer 72, three spaces (partitioned chambers) U, L₁, and L₂ partitioned by the displacer 72 are formed. As shown in FIG. 11, the space U is formed on the top side of the cylinder 71, and the spaces L₁ and L₂ are formed on the bottom side of the cylinder 71.

On the top end portion of the cylinder 71, a low-pressure side valve 82 which allows connection with a low-pressure gas chamber 81, and a high-pressure side valve 84 which allows connection with a high-pressure gas chamber 83 are arranged. The opening/closing operations of the low-pressure side valve 82 are controlled by an instruction signal 85, and those of the high-pressure side valve 84 are controlled by an instruction signal 87.

In the gas flows 77 shown in FIG. 11, a direction in which a gas flows is one direction decided by the condition at that time, as described above, and that condition is given by the moving direction of the displacer 72 and the states of the opening/closing operations of the low-pressure side valve 82 and high-pressure side valve 84.

A basic cooling cycle of the refrigerator will be described below.

Process (1): When the displacer 72 is located at the top dead point, only the low-pressure side valve 82 is opened to expand a high-pressure gas accumulated in the spaces L₁ and L₂ to produce cooling. As a result of this expansion, surrounding areas (cooling stages) of the spaces L₁ and L₂ are cooled, and the regenerators 75 and 76 are cooled by movement of the gas.

Process (2): The displacer 72 moves from the top dead point to the bottom dead point. During this movement, a low-temperature gas accumulated in the spaces L₁ and L₂ also passes through the regenerators 75 and 76, and the frigidity is accumulated in the regenerators 75 and 76. When the displacer 72 is located at the bottom dead point, the low-pressure side valve 82 is closed.

Process (3): When the high-pressure side valve 84 is opened, since a high-pressure gas enters the space U, a gas that originally exists there is adiabatically compressed. In addition, since the displacer 72 moves upward, the high-pressure gas is cooled when it passes through the regenerators 75 and 76 in the displacer 72, and moves to the spaces L₁ and L₂.

Process (4): The displacer 72 reaches the top dead point, and the high-pressure side valve 84 is closed.

Process (5): Then, the low-pressure side valve 82 is opened. This process is included in process (1) above in practice. Thus, the cycle returns to first process (1).

As described above, cooling is done by repeating processes (1) to (4). The aforementioned cycle is the basic cooling cycle. In the above basic cooling cycle, the opening/closing operations of the respective valves are controlled so that when the displacer 72 is located at the position of the top dead point, the high-pressure side valve 84 is closed, and the low-pressure side valve 82 is opened, and when the displacer 72 is located at the position of the bottom dead point, the low-pressure side valve 82 is closed, and the high-pressure side valve 84 is opened. Therefore, when the displacer 72 reaches the top or bottom dead point, the opening/closing timings of the respective valves are controlled to reverse the gas flow direction.

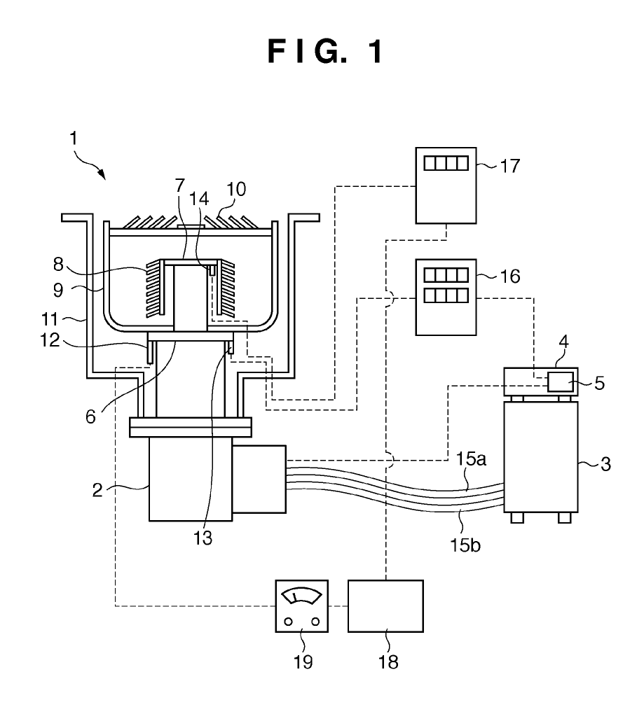

FIG. 1 is a diagram showing an example of a vacuum pump used in the vacuum pumping system of this embodiment. More specifically, the vacuum pump shown in FIG. 1 is a cryopump including a refrigerator having dual cooling stages. Referring to FIG. 1, reference numeral 1 denotes a cryopump main body; 2, a dual-stage type refrigerator; 3, a compressor; 4, a refrigerator driving power source; and 5, an inverter incorporated in the refrigerator driving power source 4.

The two-stage refrigerator 2 included in the cryopump 1 includes a first cooling stage 6, and a second cooling stage 7 which is maintained at a temperature lower than the first cooling stage 6. To the second cooling stage 7, a cryopanel 8, which is cooled to a very low temperature by the second cooling stage 7, is connected. To the first cooling stage 6, a radiation shield 9, which is cooled to a very low temperature by the first cooling stage 6, is connected. The radiation shield 9 is configured to surround the second cooling stage 7 and cryopanel 8. To an opening portion of the top portion of the radiation shield 9, a louver 10, which is cooled to a very low temperature by the first cooling stage 6 via the radiation shield 9, is arranged. Furthermore, a casing 11 is provided to surround the outer side of the radiation shield 9.

On the first cooling stage 6 of the dual-stage type refrigerator 2, an electric heater 12 as heating means for heating the first cooling stage 6 and a temperature sensor (first temperature sensor) 13 for measuring the temperature of the first cooling stage 6 are arranged. On the second cooling stage 7, a temperature sensor (second temperature sensor) 14 for measuring the temperature of the second cooling stage 7 is arranged.

The dual-stage type refrigerator 2 is connected to the compressor 3 via a high-pressure pipe 15a as a flow path through which a high-pressure gas such as helium is supplied from the compressor 3 to the refrigerator 2, and a low-pressure pipe 15b as a flow path in which a low-pressure gas such as helium flows back from the refrigerator 2 to the compressor 3. A high-pressure gas compressed by the compressor 3 is supplied to the dual-stage type refrigerator 2 via the high-pressure pipe 15a. Then, the high-pressure gas is adiabatically expanded in first and second expansion chambers (neither are shown) to cool the first cooling stage 6 and second cooling stage 7. After that, the gas flows back to the compressor 3 via the low-pressure pipe 15b.

The dual-stage type refrigerator 2 is connected to the refrigerator driving power source 4. In the dual-stage type refrigerator 2, since a high-pressure gas supplied from the compressor 3 is adiabatically expanded, a low-temperature state is obtained. The refrigerating performance is proportional to the number of times of repetition of adiabatic expansion per unit time, in other words, the number of times of repetition of high- and low-pressure states per unit time in the refrigerator. This number of times of repetition will be referred to as an “operating frequency” of the refrigerator hereinafter. In this embodiment, the inverter 5 incorporated in the refrigerator driving power source 4 controls the operating frequency of the dual-stage type refrigerator 2.

The first temperature sensor 13 and second temperature sensor 14 are respectively connected to a first temperature setting/controlling device 16 and second temperature setting/controlling device 17.

In the first temperature setting/controlling device 16, an allowable temperature range of the first cooling stage 6 is set. Note that the allowable temperature range means a setting temperature range within which the first cooling stage 6 is to be maintained throughout this specification. More specifically, the first cooling stage 6 is required to be maintained within a predetermined temperature range, for example, a temperature range from about 50K to 120K. When the temperature of the first cooling stage 6 is too low, a gas having a large vapor pressure such as argon, oxygen, or nitrogen, which is to be condensed by the second cooling stage 7 maintained at a temperature lower than the first cooling stage 6, is condensed by the first cooling stage 6. On the other hand, when the temperature of the first cooling stage 6 is too high, a gas to be originally condensed by the first cooling stage 6 cannot be condensed. Therefore, the first cooling stage 6 is required to be maintained within the predetermined temperature range, in other words, the allowable temperature range.

In the vacuum pump shown in FIG. 1, the first temperature setting/controlling device 16 controls the inverter 5 in the refrigerator driving power source 4 based on the temperature detected by the first temperature sensor 13 and the set allowable temperature range of the first cooling stage 6. That is, the operating frequency of the dual-stage type refrigerator 2 is feedback-controlled to maintain the temperature of the first cooling stage 6 to be a constant value based on the output from the first temperature sensor 13.

In the second temperature setting/controlling device 17, a target temperature range of the second cooling stage 7 is set. Note that the target temperature range means a temperature range within which the second cooling stage 7 is maintained throughout this specification. Normally, as this target temperature range, the temperature of the second cooling stage 7 requires a low temperature to some extent in consideration of the performance for condensing or adsorbing a gas. However, the second stage need not be excessively set at a low temperature in terms of a reduction of energy consumption.

Hence, the target temperature range is set to be, for example, a temperature range from 10 to 12K. The second temperature setting/controlling device 17 supplies control data to a heating controlling device 18 based on the temperature detected by the second temperature sensor 14 and the set target temperature range of the second cooling stage 7. To the heating controlling device 18, a heating power source 19 is connected. Furthermore, to the heating power source 19, the electric heater 12 is connected. The heating controlling device 18 adjusts a power supply to be supplied from the heating power source 19 to the electric heater 12 under the control of the second temperature setting/controlling device 17, thereby controlling the behavior of the electric heater 12 connected to the heating power source 19.

The first temperature setting/controlling device 16 controls the operating frequency of the refrigerator 2 by controlling the inverter 5 in the refrigerator driving power source 4, so that the temperature of the first cooling stage 6 detected by the first temperature sensor 13 maintains the set allowable temperature range. More specifically, when the detected temperature of the first cooling stage 6 is higher than an upper limit temperature of the allowable temperature range, the device 16 raises the operating frequency of the refrigerator. When the operating frequency of the refrigerator is raised, the cooling performance is enhanced since the cooling cycle is quickened, thus consequently lowering the temperature of the first cooling stage 6. On the other hand, when the detected temperature of the first cooling stage 6 is lower than a lower limit temperature of the allowable temperature range, the device 16 reduces the operating frequency of the refrigerator. When the operating frequency of the refrigerator is reduced, the cooling performance lowers since the cooling cycle is slowed down, thus consequently elevating the temperature of the first cooling stage 6.

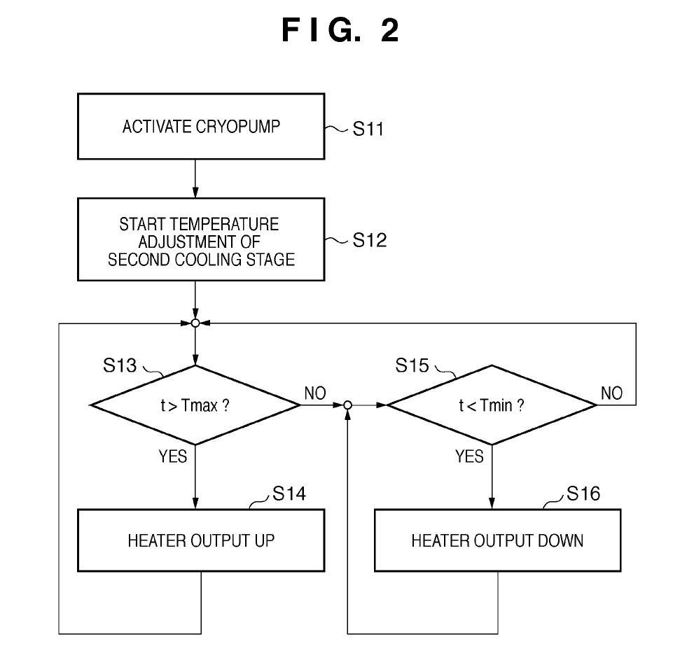

On the other hand, the second temperature setting/controlling device 17 supplies control data to the heating controlling device 18, so that the temperature of the second cooling stage 7 detected in the second temperature sensor maintains the set target temperature or target temperature range. The heating controlling device 18 controls a power supply from the heating power source 19 based on this control data, thereby controlling the behavior of the electric heater 12. More specifically, when the detected temperature of the second cooling stage 7 becomes lower than a minimum value of the target temperature range, the device 17 reduces the output from the electric heater 12; when it becomes higher than a maximum value of the target temperature range, the device 17 raises the output from the electric heater 12. An example of the behavior control of the electric heater 12 by the second temperature setting/controlling device 17 will be described below with reference to the flowchart shown in FIG. 2.

Note that in the flowchart shown in FIG. 2, t is the temperature of the second cooling stage 7 detected by the second temperature sensor 14, and Tmax is the maximum value of the target temperature range of the second cooling stage 7, which is set in the second temperature setting/controlling device 17. Also, Tmin is the minimum value of the target temperature range of the second cooling stage 7, which is set in the second temperature setting/controlling device 17.

In step S11, the cryopump is activated to start the temperature adjustment of the first cooling stage 6. After that, in step S12, the temperature adjustment of the second cooling stage 7 is also started. It is monitored if the temperature t of the second cooling stage 7 detected by the second temperature sensor 14 falls within the target temperature range.

If it is detected in step S13 that the temperature t of the second cooling stage 7 detected by the second temperature sensor 14 becomes higher than the maximum value Tmax of the target temperature range (Yes in step S13), the second temperature setting/controlling device 17 outputs a control signal to the heating controlling device 18. Upon reception of this control signal, the heating controlling device 18 raises a power supply from the heating power source 19 to the electric heater 12. Then, the output from the electric heater 12 makes the operating frequency higher within the predetermined operating frequency range (step S14).

When the thermal load on the first cooling stage 6 rises, the first temperature setting/controlling device 16 raises the operating frequency of the dual-stage type refrigerator 2 to quicken the refrigerating cycle. As a result, the refrigerating performance of the second cooling stage 7 is enhanced, and the temperature t of the second cooling stage 7 descends. During this interval, the temperature of the first cooling stage 6 is maintained within the allowable temperature range since the operating frequency of the two-stage refrigerator 2 is feedback-controlled based on the temperature of the first cooling stage measured by the first temperature sensor 13.

As for the output from the electric heater 12, the power supply from the heating power source 19 is raised step by step until the temperature t of the second cooling stage 7 detected by the second temperature sensor 14 becomes equal to or lower than the maximum value Tmax of the target temperature range. If it is detected that the temperature t of the second cooling stage 7 becomes equal to or lower than the maximum value Tmax of the target temperature range by heating of the electric heater 12 (No in step S13), it is then determined if the temperature t is equal to or higher than the minimum value Tmin of the target temperature range (step S15). If the temperature t of the second cooling stage 7 is equal to or higher than the minimum value Tmin of the target temperature range, it falls within the target temperature range. If it is confirmed that the temperature t of the second cooling stage 7 falls within the target temperature range (No in step S15), the process returns to step S13 to maintain the output from the electric heater 12 at that time, and to continue to monitor whether or not the temperature t of the second cooling stage 7 falls within the target temperature range.

On the other hand, if the temperature of the second cooling stage 7 detected by the second temperature sensor 14 becomes lower than the minimum value Tmin of the target temperature range (Yes in step S15), the second temperature setting/controlling device 17 outputs a control signal to the heating controlling device 18. Upon reception of this control signal, the heating controlling device 18 reduces a power supply from the heating power source 19 to the electric heater 12 (step S16). Then, when the output from the electric heater 12 descends, and the thermal load on the first cooling stage 6 descends, the first temperature setting/controlling device 16 reduces the operating frequency of the two-stage refrigerator 2, and the refrigerating cycle is slowed down, as described above. As a result, the refrigerating performance of the second cooling stage 7 lowers, thus raising the temperature t of the second cooling stage 7.

As for the output from the electric heater 12, the power supply of the heating power source 19 is reduced step by step until the temperature t of the second cooling stage 7 becomes equal to or higher than the minimum value Tmin of the target temperature range or the output from the electric heater 12 becomes zero. If it is detected that the temperature t of the second cooling stage 7 becomes equal to or higher than the minimum value Tmin of the target temperature range by reducing heating of the electric heater 12 (No in step S15), it is identified if that temperature is equal to or lower than the maximum value Tmax of the target temperature range (step S13). If the temperature t of the second cooling stage 7 is equal to or lower than the maximum value Tmax of the target temperature range, it falls within the target temperature range. If it is confirmed that the temperature t of the second cooling stage 7 falls within the target temperature range, the output from the electric heater 12 at that time is maintained, and it is continued to monitor whether or not the temperature t of the second cooling stage 7 falls within the target temperature range.

With the aforementioned arrangement, when the operating frequency of the two-stage refrigerator 2 falls with the normal operating frequency range, this indicates that the temperature of the first cooling stage 6 falls within the allowable temperature range, and that of the second cooling stage 7 falls within the target temperature range. Note that the operating frequency of a refrigerator normally has upper and lower limits. Since the upper limit of the rotational speed of a motor which drives a refrigerator is specified based on the power of the motor which drives the refrigerator, and the lower limit is specified due to a given rotational speed or more required for the motor to generate a required torque, the rotational speed that allows the motor to be stably driven has a range. Since the rotational speed of the motor has the upper and lower limits, the operating frequency of the refrigerator also has the upper and lower limits. The operating frequency of the refrigerator falling with the range defined by the upper and lower limits will be referred to as a “normal operating frequency” throughout this specification. For example, the normal operating frequency of the refrigerator falls within a range from 20 to 60 times per minute. That is, the operating frequency of the two-stage refrigerator 2, which frequency falls within the normal operating frequency range, means that when an arbitrary change, for example, a change in thermal load amount has occurred, the operating frequency of the refrigerator is feedback-controlled in response to that change, and a normal operation can be maintained.

The above description of the arrangement and behavior is that for the operation of the pumping means having dual cooling stages. The operation of a vacuum pump having a single cooling stage will be described below.

In the vacuum pump having a single cooling stage, the second temperature sensor 14 and second temperature setting/controlling device 17 of the means required for the vacuum pump having the dual cooling stages shown in FIG. 1 are unnecessary. In this case, the first temperature setting/controlling device 16 and heating controlling device 18 are connected in FIG. 1. The first cooling stage 6 and second cooling stage 7 shown in FIG. 1 will be described below as a “cooling stage 6” since the pump has a single cooling stage.

The first temperature setting/controlling device 16 feedback-controls the operating frequency of the refrigerator 2 based on the output from the first temperature sensor 13 attached to the cooling stage 6, so that the temperature of the cooling stage 6 detected by the first temperature sensor 13 falls within the set allowable temperature range. When the temperature of the single cooling stage 6 does not become equal to or higher than a lower limit temperature of the allowable temperature range even by reducing the operating frequency of the refrigerator of the single cooling stage 6 to the lower limit of the normal operating frequency, the heating controlling device 18 controls the heating power source 19 based on the temperature of the first temperature sensor 13 input to the first temperature setting/controlling device 16 until that temperature falls within the allowable temperature range.

More specifically, when the temperature of the first cooling stage 6 is higher than the upper limit temperature of the allowable temperature range, the operating frequency of the refrigerator 2 is raised to enhance the refrigerating performance. On the other hand, when the detected temperature of the cooling stage 6 is lower than the lower limit temperature of the allowable temperature range, the operating frequency of the refrigerator is reduced to lower the refrigerating performance. As a result, the temperature of the cooling stage 6 rises. Then, when the temperature of the cooling stage 6 does not become equal to or higher than the lower limit temperature of the allowable temperature range even by reducing the operating frequency of the refrigerator of the single cooling stage 6 to the lower limit of the normal operating frequency, the heating controlling device 18 controls the heating power source 19 based on the temperature of the first temperature sensor 13 input to the first temperature setting/controlling device 16 until the temperature falls within the allowable temperature range. Therefore, when the operating frequency of the refrigerator falls within the normal operating frequency range, this indicates that the temperature of the cooling stage 6 falls within the allowable temperature range, and when an arbitrary change has occurred, the operating frequency is feedback-controlled accordingly to maintain a normal operation.

As described above, using the vacuum pump having a single cooling stage or dual cooling stages of this embodiment, by confirming that the operating frequency of its refrigerator is within the normal operating frequency or only by controlling the operating frequency to fall within the normal operating frequency range, the temperature of the first cooling stage falls within the allowable temperature range, and that of the second cooling stage in case of the vacuum pump having the second cooling stage falls within the target temperature range.

Therefore, the normal operation can be maintained by focusing attention only on the operating frequency of the refrigerator.

In the above description, the inverter 5, refrigerator driving power source 4, first temperature setting/controlling device 16, second temperature setting/controlling device 17, heating controlling device 18, and heating power source 19 have been described as independent devices. However, these devices can be housed in a single unit. The following description will be given under the assumption that respective vacuum pumps are controlled by respective controllers each having such functions. Alternatively, all refrigerators can be controlled by a single controller in place of individual controllers.

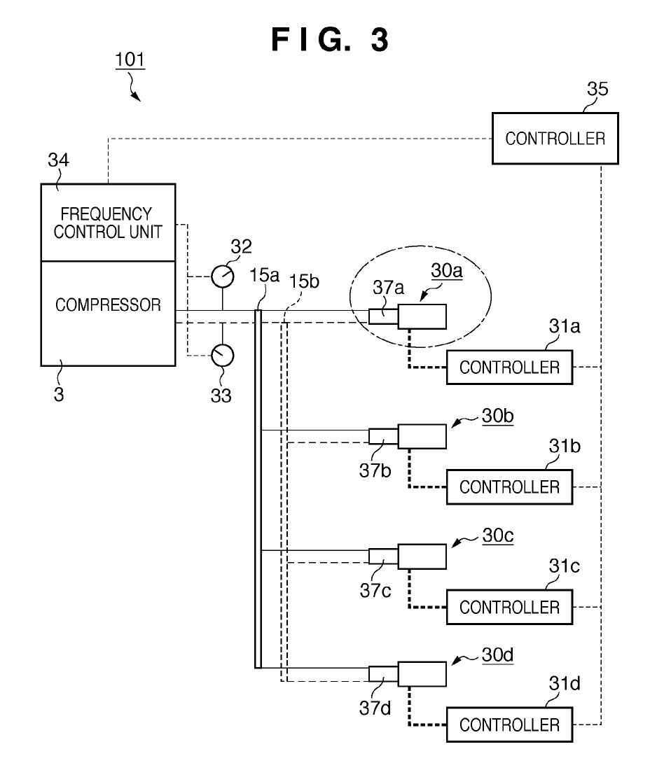

FIG. 3 is an explanatory diagram showing an example of the arrangement of a vacuum pumping system according to the first embodiment of the present invention. The embodiment shown in FIG. 3 relates to a case in which a plurality of vacuum pumps each having a single cooling stage are operated by a single compressor.

Referring to FIG. 3, reference numeral 3 denotes a compressor; and 15a and 15b, a high-pressure pipe and low-pressure pipe, respectively. Reference numerals 30a to 30d denote vacuum pumps each having a single cooling stage; and 31a to 31d, controllers for the vacuum pumps 30a to 30d. Reference numerals 32 and 33 respectively denote pressure gauges for the high- and low-pressure pipes. Reference numeral 34 denotes a frequency control unit including, for example, an inverter. The frequency control unit 34 calculates a difference between pressures from the pressure gauges 32 and 33, and controls the driving frequency of the compressor 3. Reference numeral 35 denotes a controller which integrally controls the controllers 31a to 31d of the vacuum pumps. Reference numerals 37a to 37d denote single-stage type refrigerators. The controller 35 and frequency control unit 34 serve as control means.

Each of the controllers 31a to 31d has the functions of the first temperature setting/controlling device 16, refrigerator driving power source, inverter, heating controlling device 18, and heating power source 19 described in FIG. 1. Note that reference numerals 30a to 30d denote vacuum pumps each having a single cooling stage, and cryotraps are used in this case.

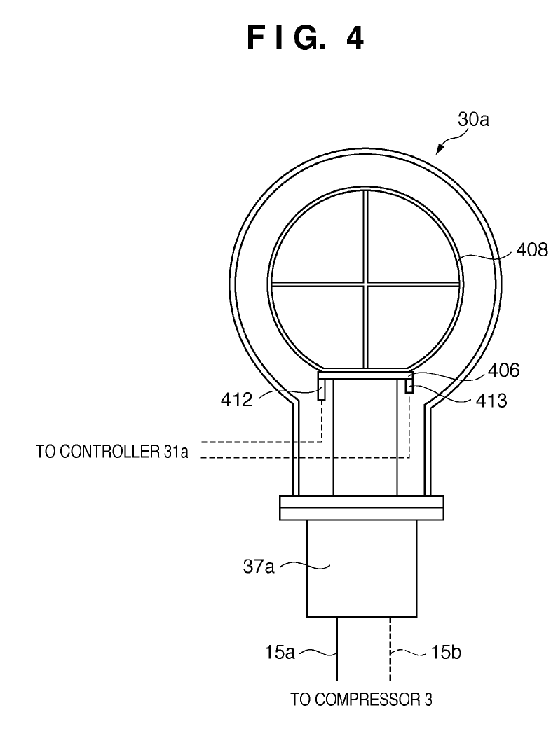

FIG. 4 is a view showing the arrangement of the vacuum pump shown in FIG. 3, which corresponds to the vacuum pump (cryotrap) 30a bounded by a one-dashed chain line in FIG. 3.

As shown in FIG. 4, the vacuum pump 30a includes a cooling stage 406, a cooling panel 408, a temperature sensor 413, an electric heater 412, the single-stage type refrigerator 37a, the high-pressure pipe 15a, and the low-pressure pipe 15b. The temperature sensor 413 and electric heater 412 are connected to the controller 31a, and the high-pressure pipe 15a and low-pressure pipe 15b are connected to the compressor 3.

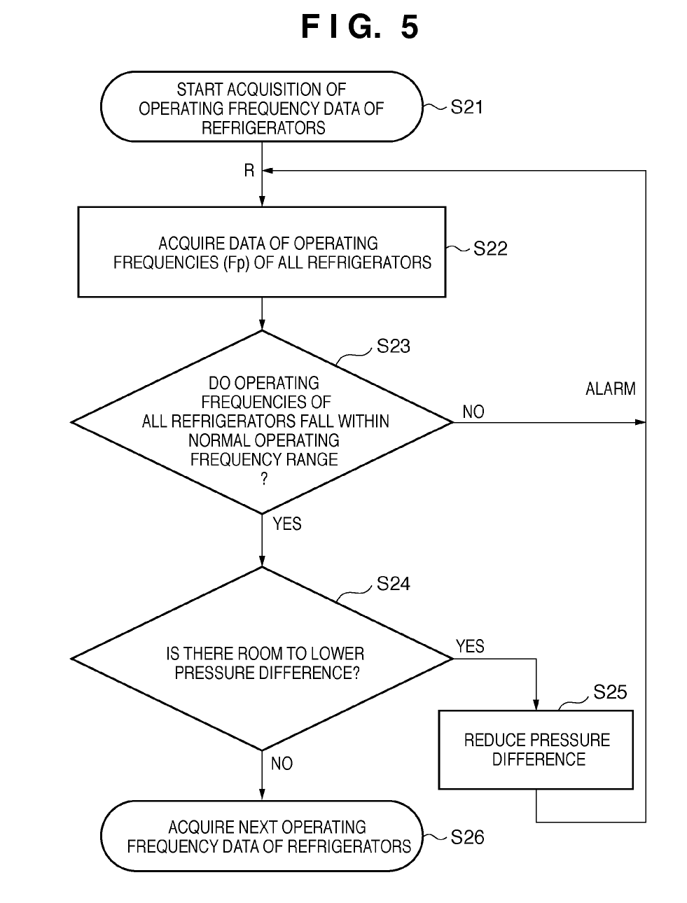

The control sequence of the vacuum pumping system shown in FIG. 3 will be described below with reference to the flowchart shown in FIG. 5.

The respective controllers 31a to 31d monitor the operating frequencies of the single-stage type refrigerators 37a to 37d of the vacuum pumps (cryotraps) 30a to 30d. The respective controllers 31a to 31d output the operating frequencies of the refrigerators 37a to 37d of the cryotraps to the controller 35 (step S21). The controller 35 acquires data of the operating frequencies of the refrigerators 37a to 37d of all the cryotraps (step S22). The controller 35 judges if the operating frequencies of the refrigerators 37a to 37d of all the cryotraps fall within the normal operating frequency range of the refrigerator (step S23). If the operating frequencies of all the refrigerators fall outside the normal operating frequency range (No in step S23), the controller 35 generates, for example, an alarm so as to inform that state.

On the other hand, if the operating frequencies of all the refrigerators fall within the normal operating frequency range (Yes in step S23), the controller 35 judges whether or not there is room to lower the pressure difference between gases in the high- and low-pressure pipes (step S24). If there is room to lower the pressure difference (Yes in step S24), the controller 35 reduces the pressure difference (step S25), and the process returns to step S22. If there is no room to lower the pressure difference (No in step S24), the controller 35 acquires the next data of the operating frequencies of the refrigerators (step S26).

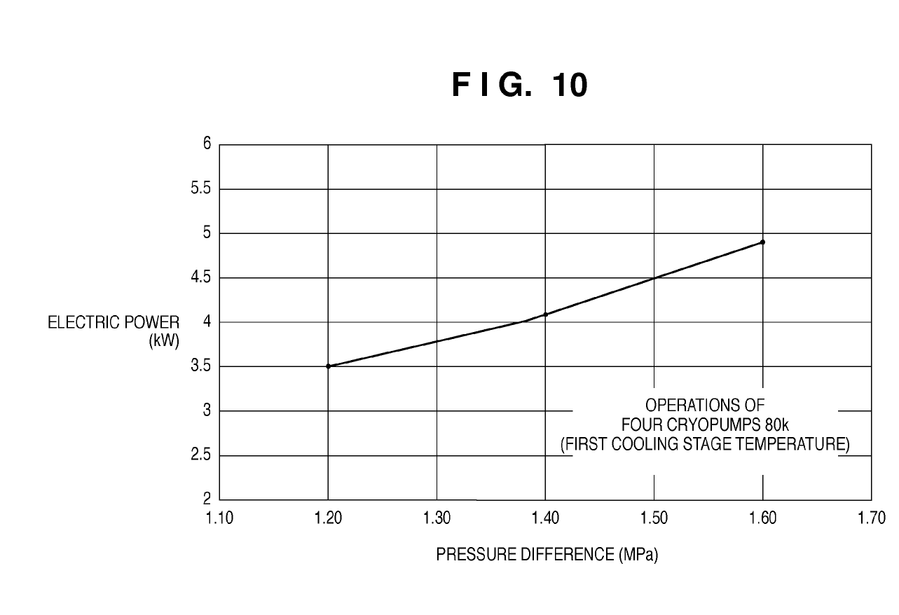

The refrigerating performance of each of the refrigerators 37a to 37d is proportional to a product between the operating frequency of the refrigerator and the pressure difference between gases in the high- and low-pressure pipes. In this embodiment, the cryotrap is used as the vacuum pump having a single cooling stage. In order to assure a given cooling performance while saving energy consumption as the whole vacuum pumping system, as shown in FIG. 10, the operating frequency of the refrigerator is raised within a possible rising range, and the pressure difference between gases in the high- and low-pressure pipes is reduced as much as possible.

Depending on the performance of the compressor, the pressure difference between gases in the high- and low-pressure pipes also has upper and lower limits. In the following description, assume that the upper limit is 1.8 MPa (about 18 atm), and the lower limit is 1.1 MPa (about 11 atm). In this case, assume that a central pressure difference is 1.4 MPa.

As described above, in order to save energy consumption as the whole vacuum pumping system, the pressure difference between gases in the high- and low-pressure pipes is to be reduced as much as possible. A reduction of the pressure difference between the high- and low-pressure pipes results in an increase in operating frequency of the refrigerator. In this embodiment, the pressure difference between gases in the high- and low-pressure pipes is controlled based on this rule.

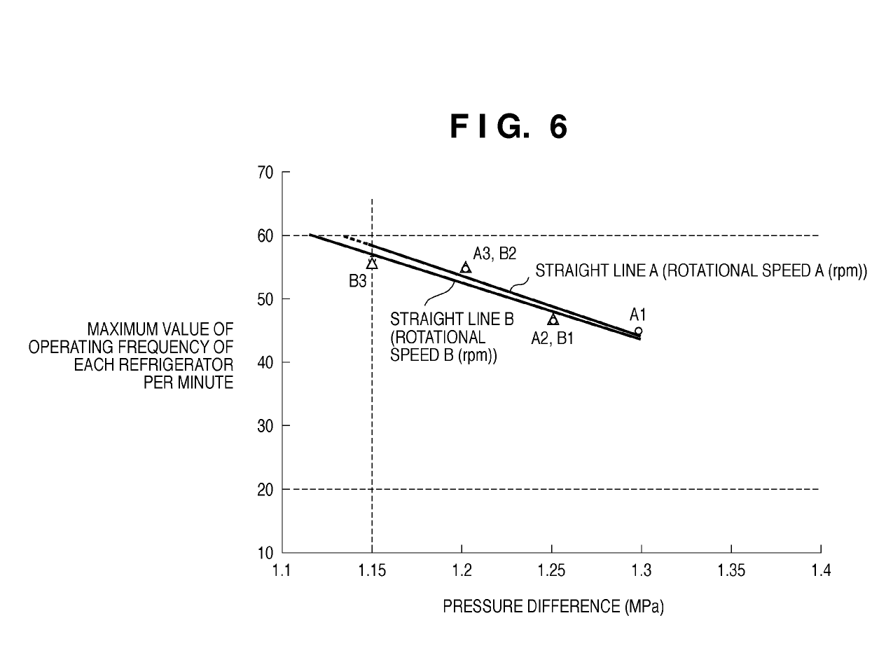

The above control method will be described in detail below with reference to FIGS. 5 and 6. FIG. 6 is a graph for explaining the method of reducing the pressure difference between gases in the high- and low-pressure pipes.

In this method, the pressure difference between helium gases in the high-pressure pipe 15a and low-pressure pipe 15b is lowered in decrements of 0.05 MPa as long as the operating frequencies of the refrigerators 37a to 37d fall within the normal operating frequency range. In FIG. 6, reference numerals A1 to A3 denote maximum values of the operating frequencies of the refrigerators respectively when the pressure differences between helium gases in the high- and low-pressure pipes are 1.2 MPa, 1.25 MPa, and 1.30 MPa. On the other hand, reference numerals B1 to B3 denote maximum values of the operating frequencies of the refrigerators respectively when the pressure differences between helium gases in the high- and low-pressure pipes are lowered by 0.05 MPa from those of the maximum values A1 to A3.

A straight line A is calculated by interpolating three points by a least square method based on the three data A1 to A3. Then, it is confirmed whether or not the maximum value of the operating frequency of the refrigerator exceeds an upper limit of an allowable operating frequency, for example, 60 times per minute even after extrapolation is made and the pressure difference is further reduced by 0.05 MPa.

In FIG. 6, since it is judged that the maximum value does not exceed 60 times per minute even after the pressure difference is reduced by 0.05 MPa, the pressure difference is reduced by 0.05 MPa.

After that, the control returns to a point R in the flowchart of FIG. 5. The data B1 to B3 in FIG. 6 (step S22 in FIG. 5) are obtained when the pressure difference is reduced by 0.05 MPa. It is confirmed if these data fall within the regular operating frequency range of the refrigerator (step S23).

After that, a straight line B which interpolates the maximum values B1 to B3 of the operating frequency of the refrigerator is calculated. As can be seen from this straight line B, when the pressure difference between helium gases in the high- and low-pressure pipes is reduced by another 0.05 MPa, the maximum value exceeds 60 times per minute as the allowable operating frequency. The controller 35 judges that there is no room to lower the operating frequency (No in step S24). The controller 35 determines that a pair of the pressure difference between helium gases in the high- and low-pressure pipes and the maximum value B3 of the operating frequency of the refrigerator shown in FIG. 6 is an operation condition which minimizes the consumption energy of the whole vacuum pumping system, and controls the vacuum pumping system to continue the operation in this state until the next acquisition opportunity of data of the operating frequencies of the refrigerators (step S26).

In this embodiment, an interpolated straight line is calculated from three points. However, the number of points is not limited to three. As the interpolation method, the least square method is used. However, the present invention is not limited to such specific method, and polynomial approximation, logarithmic approximation, power approximation, or exponential approximation may be applied.

As the method of controlling the operating frequency to fall within the normal operating frequency range in association with FIG. 6, a simple method to be described below is available in addition to the aforementioned method. For example, the upper or lower limit of the operating frequency to be controlled is controlled as a numerical value within a range inner by a predetermined value than the allowable operating frequency range. More specifically, a case will be assumed wherein the upper and lower limits of the operating frequency are respectively 60 times and 20 times per minute. Assuming that the predetermined value is 3 times per minute, the upper and lower limits of the operating frequency to be controlled are respectively controlled as 57 and 23 times per minute. The pressure difference between the high- and low-pressure pipes is changed, and the change process of the pressure difference between, for example, helium gases in the high- and low-pressure pipes is stopped once this upper or lower limit to be controlled is exceeded.

More specifically, assuming that the maximum value of the operating frequency of the refrigerator in case of 1.25 MPa is 50 times per minute, that in case of 1.20 MPa is 54 times per minute, and that in case of 1.15 MPa is 58 times per minute, the change process is stopped to prevent the pressure difference between helium gases in the high- and low-pressure pipes from being lower than 1.15 MPa. Then, the operation is continued at 1.15 MPa.

On the other hand, at the time of an activation operation which means to control the temperature of a vacuum pump using a low temperature to drop to a temperature that allows a normal operation, and at the time of a regeneration operation which means to control to recover the discharging performance by evaporating and discharging a gas that is condensed or adsorbed on an inner low-temperature portion, it is effective to increase the pressure difference between helium gases in the high- and low-pressure pipes so as to reduce a downtime of apparatus which performs processes in a vacuum chamber. This is because the cooling performance required at the time of the activation operation and the temperature rising performance required at the time of the regeneration operation are approximately proportional to the product between the pressure difference between the interiors of the high- and low-pressure pipes, and the operating frequency of the refrigerator.

The activation operation means that after a rough vacuum is created in a vacuum pump, cooling by a refrigerator is started, and the cooling stage is cooled down to a temperature state required to allow the vacuum pump to exhibit its function. During this operation, since the vacuum pump has no evacuating performance, the activation operation time is preferably as short as possible.

As a result of extensive studies, the present inventors found that at the time of the activation operation, a refrigerator is desirably operated at an operating frequency higher than a normal vacuum pumping operation and in a state in which the pressure difference between gases in the high- and low-pressure pipes is large.

Note that the vacuum pump used in this embodiment is a so-called capture type pump, which discharges a gas in a vacuum chamber by condensing or adsorbing the gas on a surface at a low temperature generated by a cooling refrigerator. For this reason, when the condensed or adsorbed gas on the low-temperature portion exceeds a predetermined amount, the condensed or adsorbed gas is required to be evaporated so that the condensed or adsorbed surface is restored to a state in which a gas is not condensed or adsorbed.

The regeneration operation means that since a vacuum pump, can have a heating function by changing its way of operation, the pump is regenerated using that function.

More specifically, the activation operation means to evaporate a condensed or adsorbed material by rising the temperature of the cooling stage and to remove it from the cooling portion such as a stage.

A refrigerator mounted in a pump has a cooling stage, a cylinder connected to one face of the cooling stage, a plate member connected to the other end face in the axial direction of the cylinder on the side opposite to the end face connected to the cooling stage, and a space formed by the cooling stage, cylinder, and plate member. The plate member has a flow path, through which the interior of the cylinder is set in one of a high-pressure state and low-pressure state by a valve manipulation. In the space, a piston-like displacer, which partitions that space into one space and the other space that communicates with the flow path, is arranged, and reciprocates in the cylinder in the axial direction. The displacer has a hollow interior, which is filled with a material that preserves a heat state.

In the pump with this arrangement, when the interior of the cylinder is in the low-pressure state, and the displacer moves closest to the plate member with the flow path, the valve manipulation is made to join the high-pressure state with the interior of the cylinder. With this manipulation, a gas in the low-pressure state, which is already present in the interior of the cylinder, is adiabatically compressed in the space of the displacer opposite to the plate member in the cylinder, and its temperature rises.

When the temperature-rising gas is passed through the displacer, the material which preserves the heat state in the displacer preserves the temperature-rising state.

When the displacer is most spaced apart from the plate member with the flow path, the valve manipulation is made to join the interior of the cylinder with the low-pressure state. With this manipulation, the gas in the high-pressure state in the cylinder is adiabatically expanded, and its temperature drops. Since most of the space (gas) in the cylinder is located between the displacer and the plate member with the flow path, most of the low-temperature gas is discharged from the refrigerator in a cold state without passing through the displacer (without preserving the low-temperature state). That is, the flow of the low-temperature gas to cross the material which is filled in the displacer and preserves the heat state does not take place. Therefore, the temperature-rising state preserved in the material which preserves the heat state in the displacer is preserved. The low-temperature gas never cools the cooling stage.

It is considered that the above operation gradually raises the temperature of the material that preserves the heat state in the displacer, and the stage temperature finally rises. As a result, a material condensed or adsorbed on a cooling portion can be evaporated, and can be removed from the cooling portion such as the stage.

As a result of extensive studies, the present inventors found that this temperature-rising performance at the time of the regeneration operation becomes larger with increasing operating frequency of the refrigerator and with increasing the pressure difference between gases in the high-pressure pipe to be supplied to the refrigerator and the low-pressure pipe. The activation can be realized in a short time by performing a heating operation opposite to a normal cooling operation of a cryopump (for example, see Japanese Patent Publication No. 4-195). That is, in the cylinder of the refrigerator, a piston-like member called the displacer reciprocates to be coaxial with the cylinder of the refrigerator. A refrigerant is filled in the central portion of the displacer, which has a structure that allows a gas to pass through in reciprocal directions. The heating operation is realized by shifting, through 180° compared to the cooling operation, the phases of opening and closing timings of valves, which control to introduce a high-pressure gas and low-pressure gas into a container of the refrigerator, with respect to the displacer.

That is, the displacer makes simple harmonic motions by a driving source such as a motor. In the normal cooling operation, a low-pressure valve is opened when a space on the valve side is smallest with respect to the displacer, and a high-pressure valve is opened when a space on the valve side is largest with respect to the displacer. However, in the heating operation, the high-pressure valve is opened when the space on the valve side is smallest with respect to the displacer, and the low-pressure valve is opened when the space on the valve side is largest with respect to the displacer. As a result of such operation, the temperatures of the first and second stages rise to evaporate a gas condensed or adsorbed there in a short time, thus regenerating the condensed or adsorbed surface.

A case will be explained below with reference to FIG. 3 wherein the plurality of vacuum pumps include a vacuum pump which performs the normal operation and that which performs the regeneration operation. At least one of the plurality of vacuum pumps 30a to 30d performs the regeneration operation, in other words, an operation that repeats an operation including a process in which a gas in a low-pressure state is adiabatically compressed when the interior of the cylinder shifts from a low-pressure state to a high-pressure state as a result of valve operations, and a process in which the displacer passes through the adiabatically compressed gas. Then, at least another one of the plurality of vacuum pumps 30a to 30d performs the normal operation, in other words, an operation that repeats an operation including a process in which a gas in a high-pressure state is adiabatically expanded when the interior of the cylinder shifts from a high-pressure state to a low-pressure state as a result of valve operations, and a process in which the displacer passes through the adiabatically expanded gas.

In the above description, the opening and closing timings of the valves for high- and low-pressure gases are shifted through 180° with respect to the displacer in the activation operation and regeneration operation, so as to explain the principle. However, in order to attain efficient operations, these timings often had better be shifted more than 180° (for example, see Japanese Patent Laid-Open No. 7-35070).

Assume that the vacuum pump during the activation operation or regeneration operation operates the refrigerator at a constant operating frequency relatively higher than that during the normal operation since the cooling performance or temperature-rising performance of the refrigerator becomes higher with increasing operating frequency of the refrigerator. During the normal operation, the operating frequency of the refrigerator is, for example, 20 to 60 times per minute. However, during the activation or regeneration operation, the refrigerator is operated at, for example, a constant value, in other words, 75 times per minute.

In this case as well, when the vacuum pumping system is configured using the vacuum pumps of this embodiment, the pressure difference between gases in the high- and low-pressure pipes can be increased while maintaining a state that allows normal processes in vacuum chambers to which vacuum pumps that undergo neither the activation operation nor the regeneration operation are connected. Because as for other vacuum pumps other than that which performs the activation operation or regeneration operation, the pressure difference between gases in the high- and low-pressure pipes can be increased up to a limit while confirming if the operating frequency falls within the normal operating frequency range. By making such manipulation via the controller 35, the vacuum pumps which perform the activation operation and regeneration operation can be quickly returned to a normal operation state while performing normal processes in vacuum chambers to which the vacuum pump which performs the activation operation or regeneration operation is not connected.

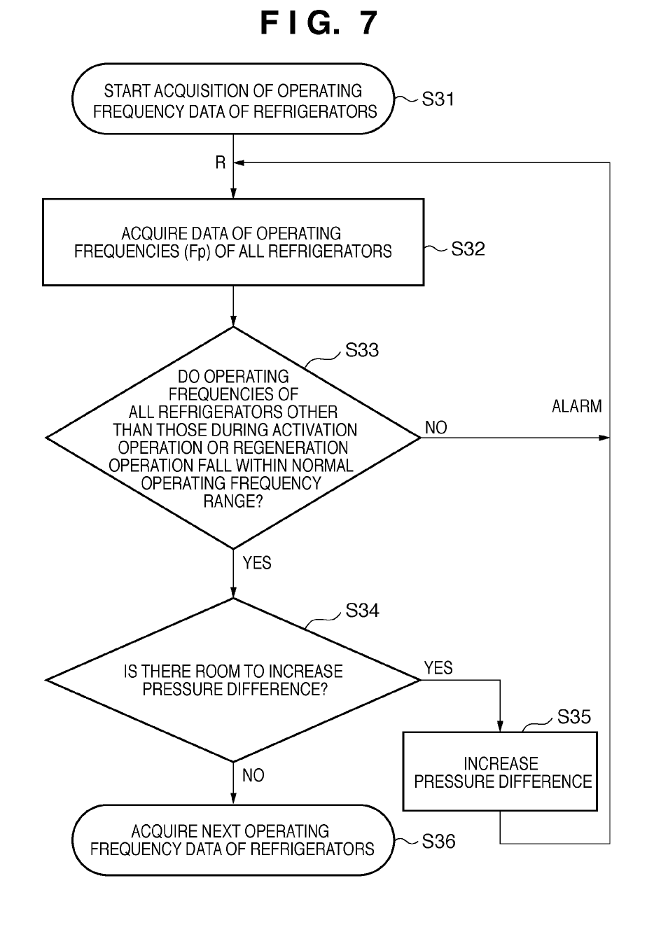

The activation operation or regeneration operation according to this embodiment will be described below with reference to the flowchart shown in FIG. 7 in association with the vacuum pumping system shown in FIG. 3.

The respective controllers 31a to 31d monitor the operating frequencies of the single-stage type refrigerators 37a to 37d of the respective vacuum pumps (cryotraps) 30a to 30d (step S31). The controllers 31a to 31d send the operating frequencies of the refrigerators 37a to 37d of the cryotraps to the controller 35 (step S32). The controller 35 judges whether or not the operating frequencies of all the cryotraps other than those during the activation operation or regeneration operation fall within the normal operating frequency range of the refrigerator (step S33). If the operating frequencies of all the refrigerators other than those during the activation operation or regeneration operation fall outside the normal operating frequency range (No in step S33), the controller 35 generates, for example, an alarm so as to inform that state.

On the other hand, if the operating frequencies of all the refrigerators other than those during the activation operation or regeneration operation fall within the normal operating frequency range (Yes in step S33), the controller 35 judges whether or not there is room to increase the pressure difference between gases in the high-pressure pipe 15a and low-pressure pipe 15b (step S34).

In case of the activation operation or regeneration operation, the operating frequency of the cryotrap which performs the activation operation or regeneration operation is maintained at a value higher than the normal operating frequency, for example, 75 times per minute. At this time, in order to enhance the cooling performance of the cryotrap which performs the activation operation or regeneration operation, it is desirable to increase the pressure difference between gases in the high-pressure pipe 15a and low-pressure pipe 15b.

Hence, the controller 35 judges if the operating frequencies of the refrigerators are maintained to fall within the normal operating frequency range even when the pressure difference between gases in the high-pressure pipe 15a and low-pressure pipe 15b is further increased by, for example, 0.05 MPa. More specifically, when the pressure difference between gases in the high-pressure pipe 15a and low-pressure pipe 15b is increased, since the operating frequencies of the refrigerators other than those during the activation operation or regeneration operation makes lower, the controller 35 judges if the minimum value of the operating frequencies of the refrigerators other than those during the activation operation or regeneration operation falls below the lower limit. If the minimum value does not fall below the lower limit (Yes in step S34), the controller 35 increases the pressure difference between gases in the high-pressure pipe 15a and low-pressure pipe 15b by, for example, 0.05 MPa (step S35). Then, the control returns to R.

The operation state to be finally reached of the vacuum pumping system (step S36) is that in which the pressure difference between gases in the high-pressure pipe 15a and low-pressure pipe 15b is set in the vicinity of a maximum pressure difference that can be reached while maintaining the operating frequencies of all the cryotraps other than those during the activation operation or regeneration operation to fall within the normal operating frequency range, in other words, in the normal operation state. As a result, the cryotraps in the activation operation or regeneration operation state can be quickly returned to a normal operation state while maintaining other cryotraps in the normal operation state.

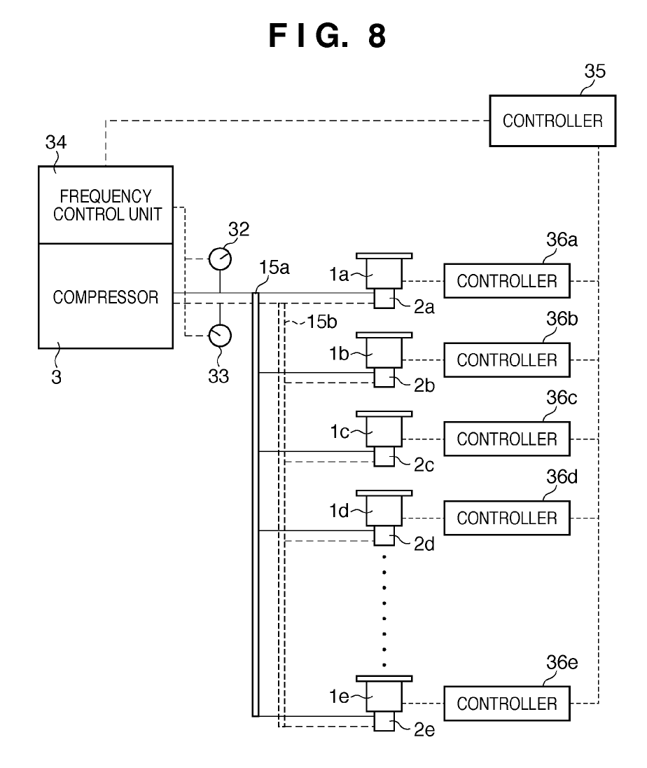

A case will be described below with reference to FIG. 8 wherein a single compressor operates a plurality of vacuum pumps each having dual cooling stages according to the second embodiment of the present invention. As a vacuum pump having dual cooling stages, a cryopump is used.

Referring to FIG. 8, reference numerals 1a to 1e denote cryopumps; 2a to 2e, refrigerators; 3, a compressor; 15a and 15b, a high-pressure pipe and low-pressure pipe, respectively; and 36a to 36e, controllers of the cryopumps 1a to 1e. Reference numerals 32 and 33 respectively denote pressure gauges for the high- and low-pressure pipes; and 34, a frequency control unit which calculates a difference between pressures from the pressure gauges 32 and 33, and controls the driving frequency of the compressor 3. Reference numeral 35 denotes a controller which integrally controls the controllers 36a to 36e of the cryopumps.

The control method of the second embodiment is the same as that described in FIGS. 5 and 6, except for the following difference. That is, the fact that the operating frequency of the cryopump falls within a normal operating frequency range indicates that the temperature of a first cooling stage falls within an allowable temperature range, and that of a second cooling stage falls within a target temperature range.

In this embodiment as well, by executing the control shown in FIG. 7 as in the first embodiment, the cryopumps which perform an activation operation and regeneration operation can be quickly returned to a normal operation state while performing normal processes in vacuum chambers to which the cryopumps that do not perform the activation operation or regeneration operation are connected.

A case will be described below with reference to FIG. 9 wherein a single compressor operates a vacuum pumping system including both vacuum pumps each having dual cooling stages and those each having a single stage according to the third embodiment of the present invention.

As a vacuum pumping means having dual cooling stages, a cryopump is used. As vacuum pumping means having a single cooling stage, a cryotrap is used.

Referring to FIG. 9, reference numerals 1a to 1c denote cryopumps; 2a to 2c, dual-stage type refrigerators of the cryopumps; 3, a compressor; 15a and 15b, a high-pressure pipe and low-pressure pipe, respectively; and 30a and 30b, cryotraps. Reference numerals 31a and 31b denote controllers of the cryotraps; and 32 and 33, pressure gauges respectively for the high- and low-pressure pipes. Reference numeral 34 denotes a frequency control unit which calculates a difference between pressures from the pressure gauges 32 and 33, and controls the driving frequency of the compressor 3; and 36a to 36c, controllers of the cryopumps 1a to 1c. Reference numeral 35 denotes a controller which integrally controls the controllers 36a to 36c of the cryopumps 1a to 1c and the controllers 36a and 36b of the cryotraps 37a and 37b.

The control method of the third embodiment is the same as that described in FIGS. 5 and 6 except for the following difference. That is, the fact that the operating frequency of the refrigerator falls within a normal operating frequency range indicates that the temperature of a first stage of the cryopump having two stages falls within an allowable temperature range, that of a second stage falls within a target temperature range, and that of a first stage of the cryotrap having a single stage falls within the allowable temperature range.

In this embodiment as well, as in the first and second embodiments, the vacuum pumps which perform an activation operation and regeneration operation can be quickly returned to a normal operation state while performing normal processes in vacuum chambers to which the vacuum pumps that do not perform the activation operation or regeneration operation are connected.

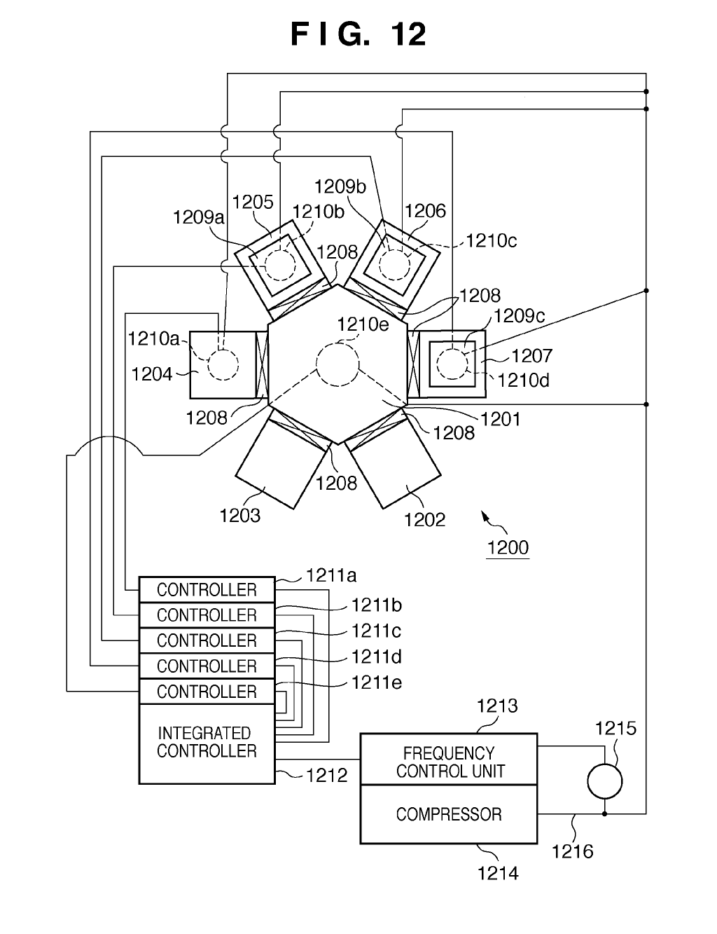

FIG. 12 shows a substrate processing apparatus 1200 using the vacuum pumping system of the present invention. This substrate processing apparatus is a cluster type sputtering apparatus which forms source and drain electrodes on a liquid crystal panel. Reference numeral 1201 denotes a substrate convey chamber which is located at the center of this apparatus, and exchanges substrates among respective substrate processing chambers. A substrate convey robot (not shown) is arranged at the central portion, and exchanges substrates among the respective substrate processing chambers. Reference numerals 1202 and 1203 denote load lock chambers; 1204, a substrate heating chamber; 1205, a first Ti film deposition chamber; 1206, an Al film deposition chamber; and 1207, a second Ti film deposition chamber. Gate valves 1208 are arranged between the substrate convey chamber 1201 and the respective substrate processing chambers. In the first Ti film deposition chamber 1205, Al film deposition chamber 1206, and second Ti film deposition chamber 1207, respective targets 1209a, 1209b, and 1209c are arranged to face substrates.

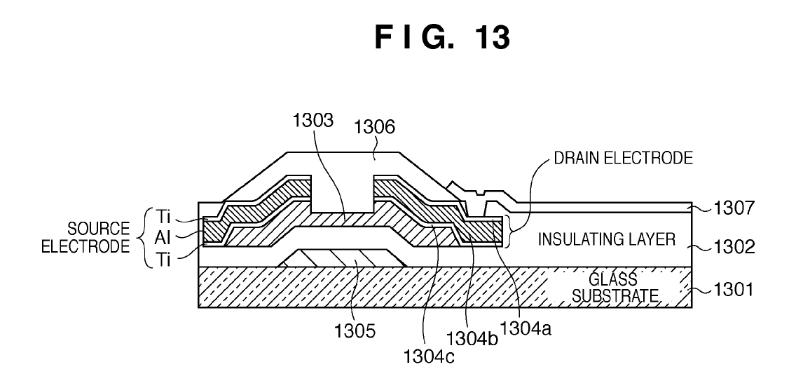

The manufacture of source and drain electrodes of a bottom-gate type thin film transistor (to be abbreviated as “TFT” hereinafter) adopted in, for example, a liquid crystal display device as an electronic device to be manufactured using the substrate processing apparatus 1200 will be described below with reference to FIG. 13. Reference numeral 1301 denotes a glass substrate; 1302, an insulating layer made of, for example, a silicon nitride film; 1303, a semiconductor layer made of amorphous Si; 1304, a source electrode and drain electrode; 1305, a gate electrode; 1306, a protection layer made of, for example, a silicon nitride film; and 1307, an indium tin oxide (to be abbreviated as “ITO” hereinafter) layer as, for example, a transparent conductive film. Note that in the TFT of this embodiment, the source and drain electrodes 1304 have a three-layered structure of Ti/Al/Ti, can assure a good contact with the semiconductor layer 1303, and can prevent diffusion of Al into amorphous Si as the semiconductor layer 1303.

A pumping system of the substrate processing apparatus 1200 which fabricates the source and drain electrodes including the three layers and uses the vacuum pumping system according to the present invention will be described below with reference to FIG. 12. Cryopumps 1210a to 1210e are respectively attached to the substrate heating chamber 1204, first Ti film deposition chamber 1205, Al film deposition chamber 1206, second Ti film deposition chamber 1207, and substrate convey chamber 1201. As each cryopump, a vertical type cryopump (indicated by a dotted line) is attached to the bottom side of each substrate processing chamber via the gate valve (not shown). The cryopumps are connected to controllers 1211 for controlling them. The respective controllers 1211 are connected to an integrated controller 1212 which controls the overall system. Note that the controllers 1211a to 1211e correspond to the controllers 36a to 36e in FIG. 8, and the integrated controller 1212 corresponds to the controller 35 in FIG. 8. The states of the respective cryopumps 1210 are input to the integrated controller 1212 which controls the overall system via the controllers 1211a to 1211e which monitor the respective cryopumps. From a compressor 1214, an He gas is supplied to and flows back from the respective cryopumps 1210 via a high-pressure pipe and low-pressure pipe 1216. A frequency control unit 1213 which drives the compressor receives a pressure difference between the He high- and low-pressure pipes, which is measured by a pressure gauge 1215. FIG. 12 illustrates a single pipe for the sake of simplicity although He supply and recovery are made via different pipes.

Since the vacuum pumping system has the aforementioned arrangement, in a normal operation of the plurality of cryopumps arranged on the plurality of processing chambers, the consumption energy during the normal operation can be saved by setting the pressure difference between high- and low-pressure He gases from the compressor to be a minimum required value.

On the other hand, even when, for example, one of the first Ti film deposition chamber and second film deposition chamber is performing an activation operation or regeneration operation, the processing chamber which performs the activation operation or regeneration operation can end the activation operation or regeneration operation in a short time and can quickly return to normal substrate processing, while other substrate processing chambers continue the normal substrate processing.

In order to fabricate the source and drain electrodes having the Ti/Al/Ti three-layered structure using the substrate processing apparatus shown in FIG. 12, a cassette which stores a plurality of substrates on each of which the semiconductor layer 1303 and layers below it are formed on the glass substrate 1301 in FIG. 13 is placed in the load lock chamber 1202 or 1203 by returning the interior of the load lock chamber 1202 or 1203 to an atmospheric pressure state while the gate valve 1208 which partitions between the load lock chamber 1202 or 1203 and the substrate convey chamber 1201 is closed. The interior of the load lock chamber 1202 or 1203 is evacuated using a low vacuum pump such as a dry pump. When the interior of the load lock chamber 1202 or 1203 is evacuated to a predetermined degree of vacuum, the gate valve 1208 between the substrate convey chamber 1201 and load lock chamber 1202 or 1203 is opened. Then, an arm of the substrate convey robot arranged at the central portion of the substrate convey chamber 1201 is rotated and extended to a position where a substrate is located, and picks up the substrate. The substrate convey robot, which picked up the substrate, retroperates its arm, and rotates about the center of the substrate convey chamber 1201 to head its arm for the substrate heating chamber 1204. After that, the gate valve between the substrate convey chamber 1201 and the load lock chamber 1202 or 1203 is closed. Then, the gate valve 1208 between the substrate convey chamber 1201 and substrate heating chamber 1204 is opened, and the substrate convey robot carries the substrate into the substrate heating chamber 1204. After the substrate is placed on a substrate support mechanism in the substrate heating chamber 1204, the arm of the substrate convey robot is retracted, and the gate valve 1208 between the substrate convey chamber 1201 and substrate heating chamber 1204 is then closed. In the substrate heating chamber 1204, heating means such as a halogen lamp heats and maintains the substrate at 120 to 150° C. The heated substrate is transferred to the next first Ti film deposition chamber 1205 by the substrate convey robot by the same manipulations as those described above, and the next substrate is transferred from the cassette in the load lock chamber 1202 or 1203 to the substrate heating chamber 1204 via the substrate convey chamber 1201. In this way, substrates in the cassette and processed substrates in respective chambers are passed in turn from the load lock chamber 1202 or 1203 to the substrate heating chamber 1204, first Ti film deposition chamber 1205, Al film deposition chamber 1206, and second Ti film deposition chamber 1207. A substrate which completes film deposition of the third layer (Ti film) is returned to a blank shelf of the cassette in the load lock chamber 1202 or 1203. After all the substrates in the cassette are processed, the cassette which stores the processed substrates is picked up from the load lock chamber 1202 or 1203. Then, a cassette which stores new substrates is placed in the load lock chamber 1202 or 1203, and the processes are repeated in the same sequence.

Note that Ti film deposition in each of the first Ti film deposition chamber 1205 and second Ti film deposition chamber 1207 forms a film having a thickness of about 50 nm at a pressure as low as 0.2 to 0.4 Pa. Likewise, Al film deposition performed in the Al film deposition chamber 1206 forms a film having a film thickness of 200 to 300 nm at a pressure as low as 0.2 to 0.4 Pa. As an achieving pressure of the aforementioned substrate processing chambers, the substrate convey chamber 1201, first Ti film deposition chamber 1205, second Ti film deposition chamber 1207, and Al film deposition chamber 1206 require a high vacuum of 5×10⁻⁵ Pa on the order of 10⁻³ Pa so as to prevent contaminations between respective substrate processing chambers. Note that the substrate heating chamber 1204 is also desirably maintained at a high vacuum during heating processing in terms of prevention of contaminations between the processing chambers as in the other substrate processing chambers described above. Therefore, the substrate heating chamber 1204 desirably adopts a cryopump which can attain a high vacuum. However, in this case, the following problem is posed. That is, the discharging characteristics of the cryopump cannot be maintained by heat input from the heating means such as a halogen lamp. Adverse effects of this problem can be suppressed by arranging a reflection plate on the upstream side of the gate valve (not shown) attached between the substrate heating chamber 1204 and cryopump 1210a.

After that, a mask is formed using a resist film on the substrate picked up from the substrate processing apparatus 1200 in the shape of the source and drain electrodes. Then, the mask is anisotropically etched by a dry etching apparatus. A protection film 1306 is formed by CVD or sputtering, thus obtaining the TFT shown in FIG. 13.

This embodiment has explained the manufacture of the source and drain electrodes of the liquid crystal display device. However, the present invention is not limited to this. The present invention can be applied a cluster or inline type substrate processing apparatus which is required to operate a plurality of refrigerators, needless to say.

Also, a device suited to be manufactured using the vacuum pumping system of the present invention is not limited to the aforementioned liquid crystal display device, and the present invention can be applied to an MRAM (Magnetic Random Access Memory; to be abbreviated as above hereinafter) for which multi-layers have to be consistently processed in a vacuum, a head for a hard disk, and a DRAM (Dynamic Random Access Memory; to be abbreviated as above hereinafter), and the like. Assume that an electronic device in this specification and the scope of the claims indicates general electronic apparatuses including a display device, an MRAM, a head of a hard disk, and a DRAM using electronic technologies.

### INDUSTRIAL APPLICABILITY

The present invention is applied to a vacuum pumping system in which a plurality of vacuum pumps each having a cooling stage are connected to a compressor and are operated by the compressor, and its operating method. Especially, the present invention can be used in a cryopump, a cryotrap, or a vacuum pumping system having cryopumps and cryotraps.

The present invention is not limited to the aforementioned embodiments, and various changes and modifications can be made without departing from the spirit and scope of the present invention. Therefore, to apprise the public of the scope of the present invention, the following claims are appended.

This application claims the benefit of the Japanese Patent Application No. 2008-253916, filed on Sep. 30, 2008, and Japanese Patent Application No. 2008-253919, filed on Sep. 30, 2008, which are hereby incorporated by reference herein in their entirety.

1. A vacuum pumping system comprising:
a plurality of vacuum pumps each of which comprises a refrigerator, which includes a first cooling stage and cools the first cooling stage, and a first temperature sensor which measures a temperature of the first cooling stage, increases the number of times of repetition of a high-pressure stage and a low-pressure stage per unit time in the refrigerator when the temperature measured by the first temperature sensor is higher than a predetermined temperature range, decreases the number of times when the temperature measured by the first temperature sensor is lower than the predetermined temperature range, and maintains the number of times when the temperature measured by the first temperature sensor falls within the predetermined temperature range;
a compressor connected to said plurality of vacuum pumps;
a high-pressure pipe which serves as a flow path through which a high-pressure gas of a common pressure is supplied from said compressor to the refrigerators of said plurality of vacuum pumps;
a low-pressure pipe which serves as a flow path through which a low-pressure gas flows back from the refrigerators of said plurality of vacuum pumps to said compressor; and
control means capable of changing a pressure difference between an internal pressure of said high-pressure pipe and an internal pressure of said low-pressure pipe according to the number of times,
wherein at least one of said plurality of vacuum pumps further comprises a second cooling stage which is cooled to a lower temperature than the first cooling stage, a second temperature sensor which measures a temperature of the second cooling stage, and heating means of the first cooling stage, and
wherein the heating means is controlled to heat based on an output from the second temperature sensor, so that the temperature of the first cooling stage is maintained to fall within the predetermined temperature range, and the temperature of the second cooling stage is maintained to fall within a second predetermined temperature range.

2. (canceled)

3. The vacuum pumping system according to claim 1, wherein said plurality of vacuum pumps include a cryotrap.

4. The vacuum pumping system according to claim 1, wherein said plurality of vacuum pumps include a cryopump.

5. The vacuum pumping system according to claim 1, wherein said at least one vacuum pump having the second cooling stage and the second temperature sensor is a cryopump.

6. An operating method of a vacuum pumping system comprising:
a plurality of vacuum pumps each comprising a refrigerator, which includes a first cooling stage and cools the first cooling stage, and a first temperature sensor which measures a temperature of the first cooling stage,
a compressor connected to the plurality of vacuum pumps,
a high-pressure pipe which serves as a flow path through which a high-pressure gas of a common pressure is supplied from the compressor to the refrigerators of the plurality of vacuum pumps, and
a low-pressure pipe which serves as a flow path through which a low-pressure gas flows back from the refrigerators of the plurality of vacuum pumps to the compressor,
the operating method comprising:
a step of controlling each of the plurality of vacuum pumps to increase the number of times of repetition of a high-pressure stage and a low-pressure stage per unit time in the refrigerator when the temperature measured by the first temperature sensor is higher than a predetermined temperature range, to decrease the number of times when the temperature measured by the first temperature sensor is lower than the predetermined temperature range, and to maintain the number of times when the temperature measured by the first temperature sensor falls within the predetermined temperature range; and
a step of decreasing a pressure difference between gases in the high-pressure pipe and the low-pressure pipe generated by the compressor so that the number of times in the refrigerator falls within a predetermined range,
wherein at least one of the plurality of vacuum pumps further comprises a second cooling stage which is cooled to a lower temperature than the first cooling stage, a second temperature sensor which measures a temperature of the second cooling stage, and heating means of the first cooling stage, and
the operating method further comprises a step of controlling the heating means to operate based on an output from the second temperature sensor, so that the temperature of the first cooling stage is maintained to fall within the predetermined temperature range, and the temperature of the second cooling stage is maintained to fall within a second predetermined temperature range.

7. (canceled)

8. A refrigerator which comprises
a cooling stage,
a cylinder which is connected to one face of the cooling stage,
a plate member which is connected to the other end face in an axial direction of the cylinder on a side opposite to the one end face of the cylinder connected to the cooling stage,
a space which is formed to be surrounded by the cooling stage, the cylinder, and the plate member,
a flow path which is formed in the plate member,
a valve which sets an interior of the cylinder in one of a high-pressure state and a low-pressure state via the flow path, and
a piston shaped displacer which partitions an interior of the space into one space and the other space communicating with the flow path,
the displacer reciprocating in an axial direction in the cylinder, and the cylinder having a hollow interior including a material which preserves a heat state,
wherein when said refrigerator performs an operation for repeating an operation including:
a process in which a gas in the low-pressure state is adiabatically compressed when the interior of the cylinder shifts from the low-pressure state to the high-pressure state as a result of an operation of the valve, and
a process in which the displacer passes through the adiabatically compressed gas,
said refrigerator operates to set the number of times of repetition of the high-pressure state and the low-pressure state per unit time in said refrigerator to be a higher value than a low-temperature normal operation, and to increase a pressure difference between the high-pressure state and the low-pressure state.

9. The refrigerator according to claim 8, wherein the higher value than the low-temperature normal operation is a constant value.

10. The refrigerator according to claim 9, wherein the constant value is a maximum value of an operating frequency of said refrigerator.

11. A vacuum pump comprising a refrigerator according to claim 8.

12. The vacuum pump according to claim 11, further comprising a cryopump.

13. The vacuum pump according to claim 11, further comprising a cryotrap.

14. A refrigerator which includes a cooling stage and cools the cooling state by adiabatic expansion of a high-pressure gas, wherein
when a vacuum pumping operation state is reached from an ambient temperature state,
said refrigerator operates to set the number of times of repetition of the high-pressure state and the low-pressure state per unit time in said refrigerator to be a higher value than a low-temperature normal operation, and to increase a pressure difference between the high-pressure state and the low-pressure state.

15. The refrigerator according to claim 14, wherein the higher value than the low-temperature normal operation is a constant value.

16. The refrigerator according to claim 15, wherein the constant value is a maximum value of an operating frequency of said refrigerator.

17. A vacuum pump comprising a refrigerator according to claim 14.

18. The vacuum pump according to claim 17, further comprising a cryopump.

19. The vacuum pump according to claim 17, further comprising a cryotrap.

20. A refrigerator comprising a cooling stage, wherein in a regeneration operation for evaporating a condensed or adsorbed material by raising a temperature of the cooling stage, said refrigerator operates to set a number of times of repetition of a high-pressure state a the low-pressure state per unit time in said refrigerator to be a higher value than a low-temperature normal operation, and to increase a pressure difference between the high-pressure state and the low-pressure state.

21. The refrigerator according to claim 20, wherein the higher value than the low-temperature normal operation is a constant value.

22. The refrigerator according to claim 21, wherein the constant value is a maximum value of an operating frequency of said refrigerator.

23. A vacuum pump comprising a refrigerator according to claim 20.

24. The vacuum pump according to claim 23, further comprising a cryopump.

25. The vacuum pump according to claim 23, further comprising a cryotrap.

26. An operating method of a refrigerator, which comprises:
a cooling stage,
a cylinder which is connected to one face of the cooling stage,
a plate member which is connected to the other end face in an axial direction of the cylinder on a side opposite to the one end face of the cylinder connected to the cooling stage,
a space which is formed to be surrounded by the cooling stage, the cylinder, and the plate member,
a flow path which is formed in the plate member,
a valve which sets an interior of the cylinder in one of a high-pressure state and a low-pressure state via the flow path, and
a piston-shaped displacer which partitions an interior of the space into one space and the other space communicating with the flow path,
the displacer reciprocating in an axial direction in the cylinder, and the cylinder having a hollow interior including a material which preserves a heat state,
the operating method comprising controlling, when the refrigerator performs an operation for repeating an operation including:
a process in which a gas in the low-pressure state is adiabatically compressed when the interior of the cylinder shifts from the low-pressure state to the high-pressure state as a result of an operation of the valve, and
a process in which the displacer passes through the adiabatically compressed gas,
the refrigerator to operate to set the number of times of repetition of the high-pressure state and the low-pressure state per unit time in the refrigerator to be a higher value than a low-temperature normal operation, and to increase a pressure difference between the high-pressure state and the low-pressure state.

27. An operating method of a refrigerator, which includes a cooling stage and cools the cooling stage by adiabatic expansion of a high-pressure gas, the operating method controlling,
when a vacuum pumping operation state is reached from an ambient temperature state,
the refrigerator to operate to set the number of times of repetition of the high-pressure state and the low-pressure state per unit time in the refrigerator to be a higher value than a low-temperature normal operation, and to increase a pressure difference between the high-pressure state and the low-pressure state.

28.-42. (canceled)

42. A substrate processing apparatus comprising a vacuum pumping system according to claim 1.

43. A manufacturing method of an electronic device, said method comprising a processing step performed by a substrate processing apparatus according to claim 42.
